(19) United States
(12) Patent Application Publication
(10) Pub. No.: US 2004/0135177 A1
(43) Pub. Date: Jul. 15, 2004

(54) Semiconductor integrated circuit having a scan test

(75) Inventor: Tsugumi Matsuishi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/687,659

(22) Filed: Oct. 20, 2003

(30) Foreign Application Priority Data
Jan. 15, 2003 (JP) 2003-006818

(51) Int. Cl. H01L 31/112

(52) U.S. Cl. 257/257

(57) ABSTRACT

A block, which is an object to be scanned, of a semiconductor integrated circuit includes a scan flip-flop and a combinational circuit. A serial-parallel conversion unit receives serial scan output data output from the scan flip-flop of the block and converts the serial scan output data into parallel scan output data. A scan output storage stores the parallel scan output data output from the serial-parallel conversion unit, and outputs the parallel scan output data stored to outside of the semiconductor integrated circuit.

### BACKGROUND OF THE INVENTION

1) Field of the Invention

The present invention relates to a semiconductor integrated circuit having a scan path for testing various defects inside an apparatus using a scan test.

2) Description of the Related Art

In recent years, many system large-scale integrations (LSI), each having a central processing unit (CPU), a digital signal processor (DSP), a random-access memory (RAM) and the like mounted on one chip have been developed whereby the scale of the semiconductor integrated circuits is becoming larger. If such a system LSI with many components mounted on a single chip is to be designed from zero, it requires long time and many man-hour to design all the components of the system LSI. Therefore, designing experience in the past is often used and combined to make the designing process faster.

If a system LSI is made using the designing experience in the past, a method to test whether the system LSI is functioning properly or not also relies on the designing experience in the past. For example, if components used in the system LSI are designed on the assumption that a one-path scan test is to be conducted, then when performing the test it is required to execute a one-path scan test.

A scan test is a test of inputting a serial scan pattern to a test target circuit, and observing a serial output signal output from the test target circuit. If the circuit is large in scale, the serial scan pattern is long and test time is also long. In a system LSI in which the past design experience is used and which requires a long scan pattern, the following two methods have been adopted so far to shorten the test time.

The first method is to change the configuration of a scan test circuit incorporated into a past design property, and to increase the number of scan paths. For example, if the number of scan paths increases from one to two, number of scan patterns are almost reduced to half, thus shortening test time. However, this method is in fact redesigning of the test circuit. As a result, this method disadvantageously requires extra man-hour in addition to that required for designing.

The second method is to input a scan pattern at high rate to shorten test time. This method is disadvantageously in view of the following reasons:

(1) Performance of LSI tester;

(2) Limit to output driving ability of measuring target LSI; and

(3) Limit to operation of measuring target LSI.

Among these reasons, the reason (3): “limit to operation of measuring target LSI” is not so serious to the present-day system LSIs because the clock frequency of the LSI is sufficiently high.

As for the reason (2): “limit to output driving ability of measuring target LSI”, the output driving ability of even a recent system LSI is often insufficient to drive the load capacity and load resistance of the observation terminal of an LSI tester. The reason is as follows. If the system LSI is mounted on an actual end purpose substrate, it does not impose heavier load than that of the observation terminal of the LSI tester. For the purpose of saving power consumption, therefore, the output driving ability of the LSI is designed to be a minimum.

Thus, there is a limit to shortening of the test time of a system LSI that has insufficient output driving ability, that uses past designing experience and that requires a long scan pattern.

Japanese Patent Application Laid-Open No. 2-82174 discloses a semiconductor integrated circuit reduces the test time. The disclosed semiconductor integrated circuit comprises a flip-flop circuit that constitutes a scan path, a parallel-serial conversion register that transmits test data supplied as parallel data from a testing apparatus in a test mode to the scan path as serial data, and a serial-parallel conversion register that converts the test data output as serial data from the scan path in the test mode into parallel data. The scan output is converted from serial to parallel data, thereby accelerating the output frequency of an output signal.

The semiconductor integrated circuit disclosed in Japanese Patent Application Laid-Open No. 2-82174, however, has the following disadvantage. Since the scan output data converted from serial data into parallel data is directly output to the outside, the time when the scan output data is output to the outside is always the same as the time when the scan test is executed. As a result, while the scan test is executed, a test other than the scan test cannot be conducted to a scan target circuit.

Moreover, according to the conventional technology, scan input/output data is directly input/output to/from an output terminal. Therefore, it is difficult to conduct a test with a clock frequency with which the system LSI is actually driven, making it disadvantageously difficult to discover a delay defect, a defect that cannot be discovered until the LSI is driven with the actual driving frequency, and the other defects.

### SUMMARY OF THE INVENTION

It is an object of this invention to at least solve the problems in the conventional technology.

The semiconductor integrated circuit according to the present invention comprises a scan target block that has at least one scan flip-flop and at least one combinational circuit and that is an object to be scanned; a serial-parallel conversion unit that receives serial scan output data output from the scan flip-flop of the scan target block and converts the serial scan output data into parallel scan output data; and a scan output storage that temporarily stores the parallel scan output data output from the serial-parallel conversion unit and outputs the parallel scan output data at a predetermined timing.

The other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 is a block diagram of a semiconductor integrated circuit according to a first embodiment of the present invention;

FIG. 2 is a block diagram of a semiconductor integrated circuit according to a second embodiment of the present invention; and

FIG. 3 is a block diagram of a semiconductor integrated circuit according to a third embodiment of the present invention.

### DETAILED DESCRIPTION

Exemplary embodiments of the semiconductor integrated circuit according to the present invention will be explained hereinafter in detail with reference to the accompanying drawings.

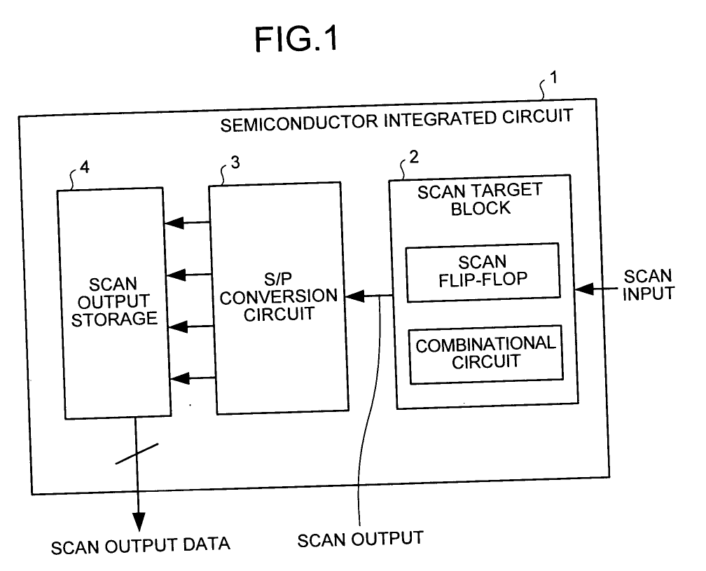

FIG. 1 is a conceptual view of a semiconductor integrated circuit according to a first embodiment of the present invention.

The semiconductor integrated circuit 1 shown in FIG. 1 comprises a scan target block 2 that includes a combinational circuit, scan flip-flops and the like, a serial-parallel (S/P) conversion circuit 3 that converts scan output data from serial to parallel data, and a scan output storage 4 that stores the scan output data.

The scan target block 2 includes ordinary flip-flops, selector-added scan flip-flops, a combinational circuit formed between the ordinary flip-flops or scan flip-flops, and the like. The scan flip-flops are cascaded to thereby constitute a shift register. In a scan mode, scan input data input as serial data is input and set to the scan flip-flops thus constituting this shift register from the outside. In a system operation mode, data is fetched into the respective scan flip-flops from the combinational circuit. By observing the data fetched into the respective scan flip-flops, it is tested whether the combinational circuit has a defect.

The data fetched into the respective scan flip-flops in the scan target block 2 is input to the S/P conversion circuit 3 as a scan output signal.

The S/P conversion circuit 3 converts the scan output signal input thereto as serial data into parallel data of, for example, four bits, and outputs the parallel data to the scan output storage 4.

The scan output storage 4 has a writable/readable RAM, and a write/read control circuit that executes controlling the write and read of data to and from the writable/readable RAM. The scan output storage 4 stores the scan output signal input in the writable/readable RAM under the write/read control of the write/read control circuit.

The scan output result temporarily stored in the RAM of the scan output storage 4 is allowed to be read by an external apparatus once input of the scan input data to the scan target block 2 is over. The external apparatus is the one that conducts manufacturing verification by comparing the scan output result with an expected value to thereby determine whether the scan target block 2 has a defect and, if there is a defect, where exactly the defect is.

The semiconductor integrated circuit 1 may be provided with a phased-lock loop that multiplies a clock signal input from the outside and outputs the multiplied clock signal as a system clock to each components of the semiconductor integrated circuit 1.

As explained above, the semiconductor integrated circuit 1 is provided with the scan output storage 4 that stores the scan output signal is provided in, making it possible to temporarily store the data S/P converted from the scan output signal in the scan output storage 4 and then to read the S/P converted data. Therefore, it is possible to output a scan result from the scan output storage 4 while conducting, for example, a different test that does not employ the scan output storage 4 to a circuit block other than the scan target block 2 in the semiconductor integrated circuit 1. As a result, the time when the scan test is executed is not restricted by the time when the scan result is output, so that various tests including the scan test can be conducted with high efficiency.

The different test mentioned above is not a test such as a scan test for allowing the LSI to perform operation different from the operation (normal operation) when the LSI is actually mounted on an apparatus so as to detect a manufacturing defect of the LSI, but it is a test for allowing the entire LSI or each constituent circuit block of the LSI to perform the same operation as the ordinary operation to verify whether the operation is performed as expected.

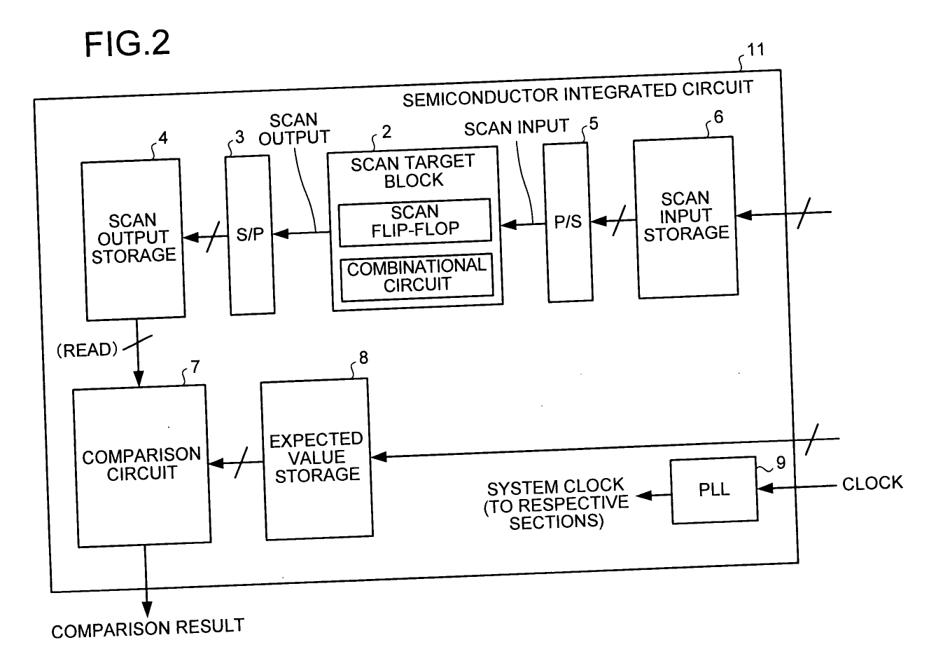

FIG. 2 is a block diagram of a semiconductor integrated circuit according to a second embodiment of the present invention.

A semiconductor integrated circuit 11 shown in FIG. 2 comprises the scan target block 2, the S/P conversion circuit 3, and the scan output storage 4 in the same manner as the semiconductor integrated circuit 1 explained in the first embodiment. The semiconductor integrated circuit 11 in addition comprises a scan input storage 6 that receives scan input data as parallel data through a data bus from the outside, a parallel-serial (P/S) conversion circuit 5 that converts the scan input data output from the scan input storage 6 as the parallel data into serial data, an expected value storage 8 that stores the expected value of a scan output result, and a comparison circuit 7 that compares the scan results stored in the scan output storage 4 with the expected value stored in the expected value storage 8, and that outputs the comparison result to the outside.

The semiconductor integrated circuit 11 also includes a phase locked loop 9 that multiplies a clock signal input from the outside and that outputs the multiplied clock signal as a system clock.

The scan input storage 6 has a writable/readable RAM, and a write/read control circuit that executes controlling the write and read of data to and from the writable/readable RAM. The scan input storage 6 stores the scan input data in this writable/readable RAM under the write/read control of the write/read control circuit.

The scan output result temporarily stored in the writable/readable RAM of the scan output storage 4 is allowed to be read once input of the scan input data into the scan target block 2 in over. The comparison circuit 7 compares the scan output result thus read with an expected value stored in the expected value storage 8, and outputs the comparison result to an external apparatus. The external apparatus determines, based on the comparison result, whether the scan target block 2 has a defect and, if there is a defect, where exactly the defect is.

As explained above, the semiconductor integrated circuit 11 is provided with the scan input storage 6 that stores the scan input data, and the scan output storage 4 that stores the scan result are provided. The scan input/output data can be temporarily stored in these memories. Therefore, it is unnecessary to input/output the scan input/output data to/from the outside through external input/output terminals during a scan test. It is thereby possible to execute the scan test using the same actual driving frequency as that of the system clock. Accordingly, it is possible to discover a delay defect, a defect that may not be able to be discovered until the LSI is driven with an actual driving frequency, and the other defects, and to shorten scan test execution time. In addition, similarly to the first embodiment, the time when the scan test is executed is not restricted by the time when the scan result is output, so that various tests including the scan test can be conducted with high efficiency.

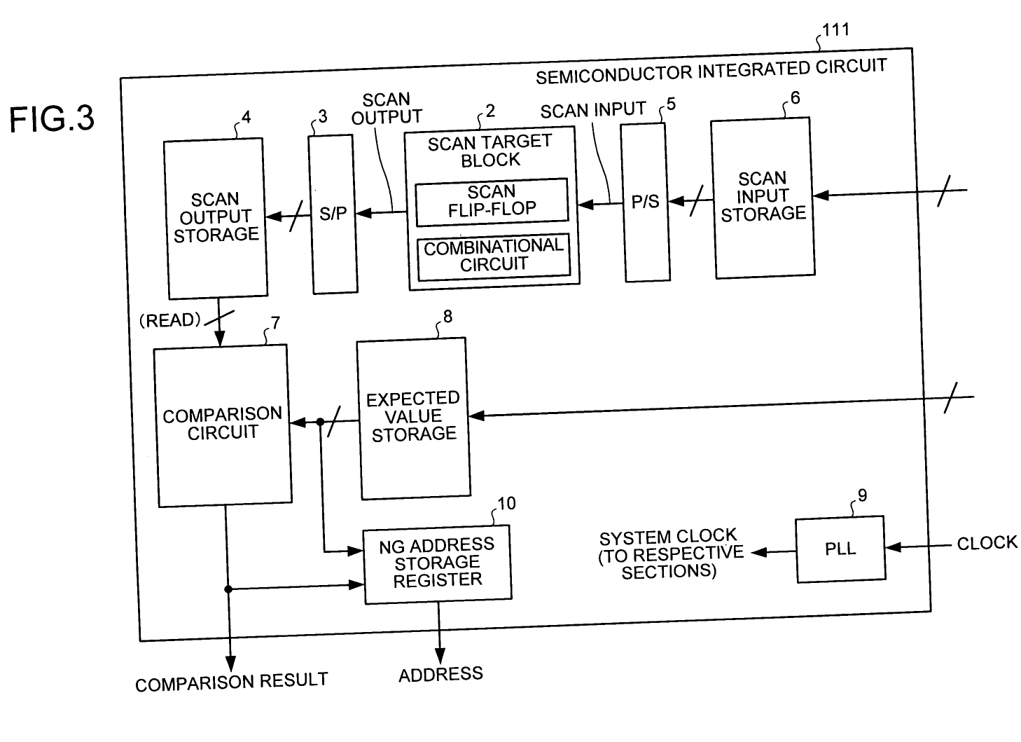

FIG. 3 is a block diagram of a semiconductor integrated circuit according to a third embodiment of the present invention. A semiconductor integrated circuit 111 shown in FIG. 3 comprises a No-Good (NG) address storage register 10 in addition to the components of the semiconductor integrated circuit 11 in the second embodiment.

The NG address storage register 10 is configured such that it receives comparison result from the comparison circuit 7 and the address from the expected value storage 8. The NG address storage register 10 holds the address of the expected value when the comparison result indicates an inconsistency between the scan result and the expected value.

The scan output result temporarily stored in the scan output storage 4 is allowed to be read once input of the scan input data to the scan target block 2 is over. The comparison circuit 7 compares the scan output result with the expected value, thus conducting manufacturing verification to the scan target block 2.

During the verification, the NG address storage register 10 holds the address of the expected value storage 8 when the output of the comparison circuit 7 indicates the inconsistency. The address stored in this NG address storage register 10 is then output to the outside of the semiconductor integrated circuit 111 together with the output of the comparison circuit 7.

As explained above, the semiconductor integrated circuit 111 is provided with the NG address storage register 10 that stores the address indicating the location of a defect. Therefore, it is advantageously possible to easily check at which address inconsistency occurs later and to thereby facilitate defect analysis in addition to the advantages of the second embodiment.

The NG address storage register 10 may store not the address of the expected value storage when the output of the comparison circuit 7 indicates inconsistency but the address of the scan output storage 4 when the output of the comparison circuit 7 indicates the inconsistency.

As explained so far, according to one aspect of the present invention, the scan output storage that stores scan output data is provided in the semiconductor integrated circuit. The scan output data is converted from serial to parallel data, temporarily stored in the scan output storage, and then read to the outside. Therefore, it is possible to output a scan result from the scan output storage while conducting a different test that does not employ the scan output storage to a circuit block other than the scan target block. As a result, the time when the scan test is executed is not restricted by the time when the scan result is output, so that various tests including the scan test can be conducted with high efficiency.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor integrated circuit comprising:
a scan target block that has at least one scan flip-flop and at least one combinational circuit and that is an object to be scanned;
a serial-parallel conversion unit that receives serial scan output data output from the scan flip-flop of the scan target block and converts the serial scan output data into parallel scan output data; and
a scan output storage that temporarily stores the parallel scan output data output from the serial-parallel conversion unit and outputs the parallel scan output data at a predetermined timing.

2. The semiconductor integrated circuit according to claim 1, wherein the scan output storage outputs the parallel scan output data to outside of the semiconductor integrated circuit at the predetermined timing.

3. The semiconductor integrated circuit according to claim 1, further comprising:
a scan input storage that stores parallel scan input data; and
a parallel-serial conversion unit that receives the parallel scan input data stored in the scan input storage, converts the parallel scan input data into serial scan input data, and inputs the serial scan input data into the scan flip-flop of the scan target block.

4. The semiconductor integrated circuit according to claim 1, further comprising:
an expected value storage that stores an expected value of the parallel scan output data; and
a comparison unit that receives the parallel scan output data from the scan output storage and the expected value from the expected value storage, compares the parallel scan output data and expected value, and outputs a result of comparison.

5. The semiconductor integrated circuit according to claim 4, further comprising:
a register that temporarily stores an address of the expected value storage when the result of the comparison indicates that the scan output data is inconsistent with the expected value.

6. The semiconductor integrated circuit according to claim 5, wherein the comparison unit outputs the result of the comparison to the outside of the semiconductor integrated circuit, and the register outputs the address of the expected value storage to the outside of the semiconductor integrated circuit.

7. The semiconductor integrated circuit according to claim 4, further comprising:
a register that temporarily stores an address of the scan output storage when the result of the comparison indicates that the scan output data is inconsistent with the expected value.

8. The semiconductor integrated circuit according to claim 7, wherein the comparison unit outputs the result of the comparison to the outside of the semiconductor integrated circuit, and the register outputs the address of the scan output storage to the outside of the semiconductor integrated circuit.

9. The semiconductor integrated circuit according to claim 1, further comprising a phase locked loop that multiplies a clock signal input from the outside of the semiconductor integrated circuit and outputs the multiplied clock signal as a system clock to the scan target block of the semiconductor integrated circuit.

10. The semiconductor integrated circuit according to claim 1, wherein the scan target block receives scan input data from outside of the semiconductor integrated circuit, and
the scan output storage outputs the parallel scan output data to outside of the semiconductor integrated circuit once the reception of the scan input data by the scan target block is over.
